(19) United States
(12) Patent Application Publication
(10) Pub. No.: US 2026/0271187 A1
(43) Pub. Date: Sep. 10, 2026

(54) COPPER NANO-INK, PRINTED CIRCUIT BOARD SUBSTRATE, AND METHOD OF MANUFACTURING PRINTED CIRCUIT BOARD SUBSTRATE

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Issei OKADA, Osaka (JP); Katsunari MIKAGE, Osaka (JP); Takuto HIDANI, Osaka (JP); Kenichiro AIKAWA, Shiga (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 19/164,679

(22) PCT Filed: Feb. 5, 2024
(86) PCT No.: PCT/JP2024/003610

§ 371 Date: Sep. 12, 2025

(30) Foreign Application Priority Data
Mar. 14, 2023 (JP) 2023-039679

(51) Int. Cl. H05K 1/09; C09D 11/037; C09D 11/52

(52) U.S. Cl. CPC H05K 1/097; C09D 11/037; C09D 11/52

(57) ABSTRACT

This copper nano-ink includes copper nanoparticles and a solvent. The copper nanoparticles have a first mean particle size of 1 nm to 200 nm, the first mean particle size is a volume-based mean diameter obtained by analyzing a scanning electron microscope image of the copper nanoparticles, the copper nanoparticles contain at least one of copper oxide and copper hydroxide, and in the copper nano-ink, a first ratio is 5.0% or less, the first ratio being a ratio of a mass ratio M2 of a total of copper oxide and copper hydroxide to a mass ratio M1 of copper, the mass ratio M2 and the mass ratio M1 being measured by a reference intensity ratio method.

### TECHNICAL FIELD

The present disclosure relates to a copper nano-ink, a printed circuit board substrate, and a method of manufacturing a printed circuit board substrate.

The present application claims priority based on Japanese Patent Application No. 2023-039679 filed on Mar. 14, 2023, and the entire contents of the Japanese patent application are incorporated herein by reference.

### BACKGROUND ART

In recent years, a copper nano-ink in which copper nanoparticles are dispersed in a solvent such as water has been used for forming a metal layer of a printed circuit board substrate. The metal layer includes a sintered body of the copper nanoparticles. The metal layer is formed by firing a coating film formed on a surface of a base film by application of the copper nano-ink (PTL 1).

### CITATION LIST

### Patent Literature

PTL 1: Japanese Unexamined Patent Application Publication No. 2021-17641

### SUMMARY OF INVENTION

A copper nano-ink according to the present disclosure is a copper nano-ink including copper nanoparticles and a solvent, wherein the copper nanoparticles have a first mean particle size of 1 nm to 200 nm, the first mean particle size is a volume-based mean diameter obtained by analyzing a scanning electron microscope image of the copper nanoparticles, the copper nanoparticles contain at least one of copper oxide and copper hydroxide, and in the copper nano-ink, a first ratio is 5.0% or less, the first ratio being a ratio of a mass ratio M2 of a total of copper oxide and copper hydroxide to a mass ratio M1 of copper, the mass ratio M2 and the mass ratio M1 being measured by a reference intensity ratio method.

### BRIEF DESCRIPTION OF DRAWING

FIG. 1 is a schematic sectional view illustrating a printed circuit board substrate according to an embodiment of the present disclosure.

### DETAILED DESCRIPTION

### Problems to be Solved by Present Disclosure

In a process of manufacturing a copper nano-ink, copper nanoparticles contained in the copper nano-ink are easily oxidized, and copper oxide (CuO, Cu₂O) is easily formed. In addition, copper hydroxide (Cu(OH)₂) is easily formed by a reaction between an alkali component used in the manufacturing process and copper ions dissolved from the copper nanoparticles. Thus, the copper oxide concentration and the copper hydroxide concentration in the copper nano-ink easily increase. The increase in the copper oxide concentration and the copper hydroxide concentration in the copper nano-ink tends to decrease electrical conductivity of a sintered body layer of the copper nanoparticles obtained by firing a coating film of the copper nano-ink. Accordingly, there is a demand for a copper nano-ink that can provide a sintered body layer of copper nanoparticles having high electrical conductivity.

An object of the present disclosure is to provide a copper nano-ink that can provide a sintered body layer of copper nanoparticles having high electrical conductivity, a printed circuit board substrate including a sintered body layer of copper nanoparticles having high electrical conductivity, and a method of manufacturing a printed circuit board substrate including a sintered body layer of copper nanoparticles having high electrical conductivity.

### Advantageous Effects of Present Disclosure

According to the present disclosure, it is possible to provide a copper nano-ink that can provide a sintered body layer of copper nanoparticles having high electrical conductivity, a printed circuit board substrate including a sintered body layer of copper nanoparticles having high electrical conductivity, and a method of manufacturing a printed circuit board substrate including a sintered body layer of copper nanoparticles having high electrical conductivity.

### DESCRIPTION OF EMBODIMENTS OF PRESENT DISCLOSURE

First, embodiments of the present disclosure will be listed and described.

(1) A copper nano-ink according to the present disclosure is a copper nano-ink including copper nanoparticles and a solvent, wherein the copper nanoparticles have a first mean particle size of 1 nm to 200 nm, the first mean particle size is a volume-based mean diameter obtained by analyzing a scanning electron microscope image of the copper nanoparticles, the copper nanoparticles contain at least one of copper oxide and copper hydroxide, and in the copper nano-ink, a first ratio is 5.0% or less, the first ratio being a ratio of a mass ratio M2 of a total of copper oxide and copper hydroxide to a mass ratio M1 of copper, the mass ratio M2 and the mass ratio M1 being measured by a reference intensity ratio method.

According to the present disclosure, it is possible to provide a copper nano-ink that can provide a sintered body layer of copper nanoparticles having high electrical conductivity, and a printed circuit board substrate including a sintered body layer of copper nanoparticles having high electrical conductivity. The expression that “first ratio is 5.0% or less” can also be described as “M2/M1 is 0.05 or less”.

(2) In (1) above, in the copper nano-ink, a second ratio may be 0.3% or less, the second ratio being a ratio of a mass-based chlorine content C2 measured by ion chromatography to a mass-based copper content C1 measured by ICP emission spectroscopy.

According to this, the copper nanoparticles are less likely to aggregate. The expression that “second ratio is 0.3% or less” can also be described as “C2/C1 is 0.003 or less”.

(3) In (1) or (2) above, the copper nanoparticles may have a second mean particle size of 5 nm to 400 nm. The second mean particle size is a number-based mean diameter measured using an ultrasonic attenuation particle size distribution analyzer.

According to this, dispersibility and stability of the copper nanoparticles in the copper nano-ink can be improved.

(4) In any one of (1) to (3) above, the first ratio may be 0.1% or more.

According to this, a thin copper oxide layer and a thin copper hydroxide layer are likely to be present around the copper nanoparticles, and affinity of the copper nanoparticles for solvents and dispersants tends to improve.

(5) A printed circuit board substrate according to the present disclosure is a printed circuit board substrate including a base film having a first main surface; and a sintered body layer of copper nanoparticles formed on the first main surface, wherein the sintered body layer has a Cu₂O content of 3.0 mass % or less, and the sintered body layer has a glossiness of 300 or more.

The printed circuit board substrate according to the present disclosure can include a sintered body layer of copper nanoparticles having high electrical conductivity.

(6) In (5) above, the sintered body layer may have a resistivity of 100 μsΩ·cm or less. According to this, the electrical conductivity of the sintered body layer is further improved. When the sintered body layer is subjected to electroplating, a good conducting property is obtained if the resistivity of the sintered body layer is 100 μΩ·cm or less.

(7) A method of manufacturing a printed circuit board substrate according to the present disclosure is a method of manufacturing the printed circuit board substrate according to (5) or (6) above, the method including coating the base film with the copper nano-ink according to any one of (1) to (4) above; drying a coating film of the copper nano-ink; and firing a dry film of the copper nano-ink. In the firing, the sintered body layer is formed on the base film.

This manufacturing method enables manufacturing of a printed circuit board substrate including a sintered body layer of copper nanoparticles having high electrical conductivity.

### DETAILS OF EMBODIMENTS OF PRESENT DISCLOSURE

Specific examples of a copper nano-ink and a printed circuit board substrate according to the present disclosure will be described below.

In the present disclosure, when one or more numerical values are described as each of the lower limit and the upper limit of a numerical range, a combination of any one numerical value described as the lower limit and any one numerical value described as the upper limit is also disclosed. For example, when a1, b1, and c1 are described as lower limits and a2, b2, and c2 are described as upper limits, a1 to a2, a1 to b2, a1 to c2, b1 to a2, b1 to b2, b1 to c2, c1 to a2, c1 to b2, and c1 to c2 are disclosed.

### Embodiment 1: Copper Nano-Ink

A copper nano-ink according to an embodiment (hereinafter, also referred to as “Embodiment 1”) of the present disclosure includes copper nanoparticles and a solvent. The copper nanoparticles have a first mean particle size of 1 nm to 200 nm. The first mean particle size is a volume-based mean diameter obtained by analyzing a scanning electron microscope image of the copper nanoparticles. The copper nanoparticles contain at least one of copper oxide and copper hydroxide. In the copper nano-ink, a first ratio is 5.0% or less, the first ratio being a ratio of a mass ratio M2 of a total of copper oxide and copper hydroxide to a mass ratio M1 of copper, the mass ratio M2 and the mass ratio M1 being measured by a reference intensity ratio method.

In the copper nano-ink, the first ratio is 5.0% or less, and thus the contents of copper oxide and copper hydroxide in the copper nano-ink are small. Accordingly, use of this copper nano-ink can provide a sintered body layer of copper nanoparticles having high electrical conductivity.

### <Copper Nanoparticles>

### <<First Mean Particle Size>>

The copper nanoparticles have a first mean particle size of 1 nm to 200 nm. The lower limit of the first mean particle size of the copper nanoparticles is 1 nm and may be 10 nm or 20 nm. When the first mean particle size of the copper nanoparticles is 1 nm or more, dispersibility and stability of the copper nanoparticles in the copper nano-ink can be improved. The upper limit of the first mean particle size of the copper nanoparticles is 200 nm and may be 150 nm. When the first mean particle size of the copper nanoparticles is 200 nm or less, voids are less likely to increase in a sintered body layer obtained by firing the copper nano-ink, and electrical conductivity of the sintered body layer is improved. The first mean particle size of the copper nanoparticles may be 10 nm to 150 nm or 20 nm to 150 nm.

The first mean particle size of the copper nanoparticles is a volume-based mean diameter obtained by analyzing a scanning electron microscope image of the copper nanoparticles. The first mean particle size corresponds to a volume-based mean diameter based on the particles sizes of the copper nanoparticles. The method for measuring the first mean particle size of copper nanoparticles is as follows. A polyimide film is prepared, one surface of the polyimide film is coated with a copper nano-ink, and the resulting coating film is dried to form a dry film. The surface of the dry film is observed with a scanning electron microscope (SEM) (“SU-8020” (trademark), manufactured by Hitachi High-Tech Corporation) to obtain a SEM image. The observation magnification is 100,000 times. Two rectangular measurement fields of view of 900 nm×1,300 nm are set in the SEM image. The two measurement fields of view are set so as not to overlap each other. Image processing software (“Image-Pro” (trademark), manufactured by Hakuto Co., Ltd.) is used to measure area equivalent circle diameters of all copper nanoparticles in the two measurement fields of view, and the volume-based mean diameter is calculated. The “area equivalent circle diameter of a copper nanoparticle in a measurement field of view” refers to the diameter of a circle having an area equal to the area of the copper nanoparticle in the measurement field of view. The volume-based mean diameter is also referred to as a mean volume diameter (MV) and is defined by a formula 1 below.

$$MV = ( \sum Vi \cdot di ) / \sum ( Vi ) \qquad Formula 1$$

In the formula 1, Vi represents a volume per particle, and di represents a particle size.

It has been confirmed that, even when a plurality of measurement fields of view are arbitrarily set for a copper nano-ink produced at the same time, there is no significant difference between the measured values.

### <<First Ratio>>

The copper nanoparticles contain at least one of copper oxide and copper hydroxide. In the copper nano-ink, a first ratio is 5.0% or less, the first mass ratio being a ratio of a mass ratio M2 of a total of copper oxide and copper hydroxide to a mass ratio M1 of copper, the mass ratio M2 and the mass ratio M1 being measured by a reference intensity ratio method. The mass ratio M2 of the total of copper oxide and copper hydroxide is a total of a mass ratio of copper oxide and a mass ratio of copper hydroxide. Copper oxide includes CuO and Cu₂O. Copper hydroxide is Cu(OH)₂. It is presumed that copper oxide (CuO and Cu₂O) contained in the copper nanoparticles is formed by oxidation of copper of the copper nanoparticles in a process of manufacturing the copper nano-ink. It is presumed that copper hydroxide (Cu(OH)₂) contained in the copper nanoparticles is formed by a reaction between an alkali component used in the synthesis and copper ions dissolved from the copper nanoparticles in the process of manufacturing the copper nano-ink.

The upper limit of the first ratio is 5.0% and may be 4.5%, 4.0%, 3.5%, 3.0%, 2.4%, or 2.0%. When the first ratio is 5.0% or less, the contents of copper oxide and copper hydroxide in the copper nano-ink are small; therefore, a sintered body layer of copper nanoparticles having high electrical conductivity can be provided. The lower limit of the first ratio is not particularly limited. The first ratio may be 0% or more, more than 0%, or 0.1% or more. When the first ratio is 0.1% or more, a thin copper oxide layer and a thin copper hydroxide layer are likely to be present around the copper nanoparticles, and affinity of the copper nanoparticles for solvents and dispersants tends to improve. The first ratio may be 0% to 5.0%, more than 0% and 5.0% or less, 0.1% to 5.0%, 0.1% to 4.0%, 0.1% to 3.0%, 0.1% to 2.4%, or 0.1% to 2.0%.

Whether copper nanoparticles contain at least one of copper oxide and copper hydroxide can be checked by the following procedure. A polyimide film is prepared, and one surface of the polyimide film is coated with a copper nano-ink. The resulting coating film is dried in a vacuum to form a dry film. For copper nanoparticles contained in the dry film are subjected to mapping analysis in a vacuum using an energy dispersive X-ray spectroscope (EDX, “JED-2300T” (trademark), manufactured by JEOL Ltd.) attached to a scanning transmission electron microscope (STEM, “ARM200F” (trademark), manufactured by JEOL Ltd.) (STEM-EDX). When at least one of copper oxide and copper hydroxide is confirmed in edge portions of the copper nanoparticles in the mapping image, it is determined that the copper nanoparticles contain at least one of copper oxide and copper hydroxide.

The first ratio is determined by obtaining an XRD (X-ray diffraction) spectrum of the copper nano-ink by an XRD method and using a reference intensity ratio (RIR) method based on the XRD spectrum. Conditions for the X-ray diffraction measurement are as follows.
Measurement apparatus: “SmartLab” manufactured by Rigaku Holdings Corporation
X-ray used: Cu-Ka
Excitation conditions: 45 kV, 200 mA
Incident optical system: CBO-f
Sample stage: XY stage
Slit size: 0.8 mm
Mask: 0.5 mm
Light-receiving optical system: HyPix-3000 (two dimension)
Scanning method: 2θ-θ scan
Measurement range: 2θ is from 30° to 80°.
Step width: 0.03°
Scan speed: 2°/min

In the XRD spectrum of the copper nano-ink, the integrated intensity in the strongest line of each of Cu, Cu₂O, CuO, and Cu(OH)₂ is determined. The mass ratio of each component is calculated from this integrated intensity using an RIR value registered in a database. In the XRD spectrum, the strongest line of Cu is present at a diffraction angle 2θ of 43.30°, the strongest line of Cu₂O is present at a diffraction angle 2θ of 36.44°, the strongest line of CuO is present at a diffraction angle 2θ of 35.54° or 38.73°, and the strongest line of Cu(OH)₂ is present at a diffraction angle 2θ of 23.83°. The RIR value of each component is specified with reference to the database of powder X-ray diffraction disclosed by the International Centre for Diffraction Data (ICDD).

The mass ratio of Cu corresponds to the mass ratio M1 of copper, and a total of the mass ratio of Cu₂O, the mass ratio of CuO, and the mass ratio of Cu(OH)₂ corresponds to the mass ratio M2 of the total of copper oxide and copper hydroxide. The first ratio is calculated on the basis of the mass ratio M1 of copper and the mass ratio M2 of the total of copper oxide and copper hydroxide.

### <<Second Mean Particle Size>>

The copper nanoparticles may have a second mean particle size of 5 nm to 600 nm. The lower limit of the second mean particle size of the copper nanoparticles may be 5 nm, 25 nm, or 80 nm. When the second mean particle size of the copper nanoparticles is 5 nm or more, dispersibility and stability of the copper nanoparticles in the copper nano-ink can be improved. The upper limit of the second mean particle size of the copper nanoparticles may be 600 nm, 400 nm, or 250 nm. When the second mean particle size of the copper nanoparticles is 600 nm or less, in particular, 400 nm or less, voids are less likely to increase in a sintered body layer obtained by firing the copper nano-ink, and electrical conductivity of the sintered body layer is improved. The second mean particle size of the copper nanoparticles may be 25 nm to 400 nm or 80 nm to 250 nm.

The second mean particle size is a number-based mean diameter measured using an ultrasonic attenuation particle size distribution analyzer. The second mean particle size corresponds to a number-based mean diameter based on a volume equivalent sphere diameter of an aggregate of the copper nanoparticles in the copper nano-ink. The “volume equivalent sphere diameter of an aggregate of copper nanoparticles” refers to the diameter of a sphere having a volume equal to the volume of the aggregate of copper nanoparticles. The ultrasonic attenuation particle size distribution analyzer used may be “DT-100” (trademark) manufactured by Dispersion Technology Inc. can be used. The measurement range is 5 nm or more and 1,000 μm. The number-based mean diameter is also referred to as a mean number diameter (MN) and is defined by a formula 2 below.

$$MN = \sum ( ni \cdot di ) / \sum ni \qquad Formula 2$$

In the formula 2, ni represents the number of particles, and di represents a particle size.

### <Second Ratio>

The copper nano-ink may contain chlorine. It is presumed that chlorine in the copper nano-ink is derived from titanium trichloride and copper (II) chloride (CuCl₂) used in the production of copper nanoparticles. In the copper nano-ink, a second ratio may be 0.45% or less, 0.3% or less, 0.2% or less, 0.15% or less, 0.06% or less, or 0.02% or less, the second ratio being a ratio of a mass-based chlorine content C2 (mass %) measured by ion chromatography to a mass-based copper content C1 (mass %) measured by ICP emission spectroscopy. When the second ratio is 0.45% or less, in particular, 0.3% or less, dispersibility and stability of the copper nanoparticles in the copper nano-ink can be improved. The lower limit of the second ratio is not particularly limited. The second ratio may be, for example, 0% or more, more than 0%, or 0.02% or more. The second ratio may be 0% to 0.45% or 0.02% to 0.30%.

The second ratio is measured by the following procedure. The copper nano-ink is diluted with water at a dilution factor of 50,000 to prepare a diluted solution. A mass-based copper content (unit: mass %) in the diluted solution is measured by ICP emission spectroscopy. The measurement by ICP emission spectroscopy is performed using “iCAP6300” (trademark) manufactured by Thermo Fisher Scientific K.K. A mass-based chlorine content (unit: mass %) in the diluted solution is measured by ion chromatography. The measurement by ion chromatography is performed using an ion chromatography system “ICS-2100” (trademark) manufactured by Thermo Fisher Scientific K.K. The second ratio is equal to {mass-based chlorine content (mass %) in diluted solution/mass-based copper content (mass %) in diluted solution}.

### <Solvent>

The solvent of the copper nano-ink is not particularly limited. Water may be used as the solvent of the copper nano-ink.

In the case where water is used as the solvent, the water content in the copper nano-ink may be 20 parts by mass to 1,900 parts by mass per 100 parts by mass of the copper nanoparticles. When the water content is 20 parts by mass or more, the content of the copper nanoparticles in the copper nano-ink is not excessive, and a base film can be uniformly coated with the copper nano-ink. When the water content is 1,900 parts by mass or less, the content of the copper nanoparticles in the copper nano-ink is sufficient, and a good sintered body layer having a necessary thickness and a necessary density can be formed on a surface of the base film of the printed circuit board substrate.

### <Dispersant>

The copper nano-ink may contain a dispersant. Examples of the dispersant include polyethyleneimine, polyvinylpyrrolidone, polyvinyl alcohol, and polyethylene glycol. When the copper nano-ink contains the dispersant, the particles are less likely to aggregate and less likely to settle. These dispersants may be used alone or as a mixture of two or more thereof. Hereinafter, polyethyleneimine, polyvinylpyrrolidone, polyvinyl alcohol, and polyethylene glycol are collectively referred to as a “dispersant”.

In the copper nano-ink, the ratio of the mass of the dispersant to the mass of copper may be 0.01% to 2.5% or 0.1% to 1.5%. In the case where two or more dispersants are used, the mass of the dispersant refers to a total mass of the dispersants.

### <Additive>

The copper nano-ink may contain an additive as long as the advantageous effects of the present disclosure are not impaired. The additive is, for example, ascorbic acid or an amine-based polymer.

### <Method of Manufacturing Copper Nano-Ink>

A method of manufacturing a copper nano-ink will be described. The method of manufacturing a copper nano-ink includes a step of precipitating copper nanoparticles, a step of washing the copper nanoparticles, and a step of dispersing the copper nanoparticles in a solvent.

### <<Step of Precipitating Copper Nanoparticles>>

In the step of precipitating copper nanoparticles, copper nanoparticles are precipitated by a liquid-phase reduction method. In this step, copper ions are reduced in an aqueous solution containing a reducing agent to precipitate copper nanoparticles. The liquid-phase reduction method is, for example, a titanium redox process.

The step of precipitating copper nanoparticles includes a step of preparing an aqueous solution of a reducing agent and a step of reducing copper ions.

In the step of preparing an aqueous solution of a reducing agent, an aqueous solution containing a reducing agent that reduces copper ions is prepared. In the step of reducing copper ions, an aqueous solution containing copper ions is put into the aqueous solution of the reducing agent, or a water-soluble metal compound that generates copper ions upon ionization is put into the aqueous solution of the reducing agent.

Various reducing agents that can reduce copper ions and cause precipitation in the reaction system of the liquid phase (aqueous solution) can be used. Examples of the reducing agent include sodium borohydride, sodium hypophosphite, hydrazine, transition metal ions such as a trivalent titanium ion (for example, titanium trichloride) and a divalent cobalt ion, ascorbic acid, reducing sugars such as glucose and fructose, and polyhydric alcohols such as ethylene glycol and glycerin. A trivalent titanium ion may be used as the reducing agent. A liquid-phase reduction method in which trivalent titanium ions are used as the reducing agent is a titanium redox process. In the titanium redox process, copper ions are reduced by redox action when trivalent titanium ions are oxidized to tetravalent titanium ions, so that copper nanoparticles are precipitated. According to the titanium redox process, copper nanoparticles having a small and uniform particle size are easily formed.

For example, a complexing agent, a dispersant such as polyvinyl alcohol, or a pH adjuster may be further added to the aqueous solution of the reducing agent.

Various publicly known complexing agents may be used as the complexing agent. Examples of the complexing agent include sodium citrate, sodium tartrate, sodium acetate, gluconic acid, sodium thiosulfate, ammonia, and ethylenediaminetetraacetic acid. One or two or more of these complexing agents may be used. Sodium citrate may be used as the complexing agent.

Examples of the dispersant blended in the aqueous solution of the reducing agent include polyethyleneimine, polyvinylpyrrolidone, and polyvinyl alcohol.

The pH adjuster blended in the aqueous solution of the reducing agent is, for example, a typical acid or alkali such as hydrochloric acid, sulfuric acid, nitric acid, sodium hydroxide, sodium carbonate, or ammonia. The pH of the aqueous solution of the reducing agent is, for example, 5 to 13. If the pH of the aqueous solution of the reducing agent is excessively low, the precipitation rate of metal is slow, and the particle size distribution tends to be broad. If the pH of the aqueous solution of the reducing agent is excessively high, the precipitation rate of metal is excessively high, and the precipitated copper nanoparticles may aggregate to form cluster-like or chain-like coarse particles.

In the step of reducing copper ions, copper ions are put into the aqueous solution of the reducing agent. In the aqueous solution of the reducing agent, the copper ions are reduced by the reducing agent, and copper nanoparticles precipitate.

When a water-soluble copper compound is dissolved in water, copper ions are generated by ionization of the water-soluble copper compound. Examples of the water-soluble copper compound include copper (II) nitrate trihydrate (Cu(NO₃)₂·3H₂O), copper (II) sulfate pentahydrate (CuSO₄·5H₂O), copper (II) chloride (CuCl₂), and copper (II) sulfate pentahydrate (CuSO₄·5H₂O).

If the water-soluble copper compound is directly put into the aqueous solution of the reducing agent, a reaction proceeds locally immediately after the compound is put. In such a case, the particle size of the copper nanoparticles becomes nonuniform, and the particle size distribution tends to be broad. Therefore, the water-soluble copper compound may be dissolved in water, and the aqueous solution containing copper ions may be put into the aqueous solution of the reducing agent.

The lower limit of the temperature of the aqueous solution of the reducing agent in the step of reducing copper ions may be 0° C. or 15° C. When the temperature is 0° C. or higher, a good reduction reaction efficiency can be obtained. The upper limit of the temperature of the aqueous solution of the reducing agent in the step of causing precipitation may be 100° C., 60° C., or 50° C. When the temperature is 100° C. or lower, the growth rate of copper nanoparticles is moderate, and the particle size can be easily adjusted.

### <<Step of Washing Copper Nanoparticles>>

In the step of washing the copper nanoparticles, the copper nanoparticles precipitated in the aqueous solution of the reducing agent are washed.

The solution containing the precipitated copper nanoparticles after the reaction is left to stand for 12 hours or more to settle the copper nanoparticles. Subsequently, the supernatant is removed by decantation. About 95% of the supernatant is removed.

After the removal of the supernatant, the solution containing the sediment of the copper nanoparticles is washed using an aqueous solution containing a dispersant. Specifically, an aqueous solution containing a dispersant is added to the solution containing the sediment of the copper nanoparticles, and stirring is performed for 60 minutes with a stirrer to prepare a liquid mixture. Hereinafter, an aqueous solution containing a dispersant is also referred to as an “aqueous solution of a dispersant”. A dispersant that is the same as the dispersant used in the step of precipitating copper nanoparticles can be used. Examples of the dispersant include polyethyleneimine, polyvinylpyrrolidone, polyvinyl alcohol, and polyethylene glycol. Next, the liquid mixture after stirring is subjected to solid-liquid separation by centrifugal separation to recover a dehydrated solid containing the copper nanoparticles and the dispersant. Hereinafter, washing a solution containing a sediment of copper nanoparticles using an aqueous solution containing a dispersant is also referred to as “washing with a dispersant”.

Pure water is added to the solid, the solid is dispersed with a mixer, and centrifugal separation is then performed to recover the dehydrated solid. Hereinafter, this treatment is also referred to as “washing with pure water”. Washing with pure water is performed again, and a solid containing the copper nanoparticles is recovered.

Through the step of washing the copper nanoparticles, ion components that do not adsorb on the copper nanoparticles can be removed.

The solid containing the recovered copper nanoparticles may be turned into a powder through a step of drying, crushing, or the like. To prevent aggregation, this solid may be dispersed in an aqueous solution at a high concentration without being turned into a powder.

### <<Step of Dispersing Copper Nanoparticles>>

In the step of dispersing the copper nanoparticles, the solid containing the copper nanoparticles is dispersed in a solvent so as to give an appropriate concentration of the copper nanoparticles. Thus, a copper nano-ink can be obtained.

The solvent of the copper nano-ink may be water. As the solvent of the copper nano-ink, an organic solvent compatible with water may be used together with water. Examples of the organic solvent include alcohols such as ethanol, IPA, ethylene glycol, and glycerin; and glycol ethers such as diethylene glycol monobutyl ether.

### <<Step of Adding Additive>>

The method of manufacturing a copper nano-ink may further include a step of adding an additive such as ascorbic acid or an amine-based polymer to the dispersion liquid of the copper nanoparticles.

### Embodiment 2: Printed Circuit Board Substrate

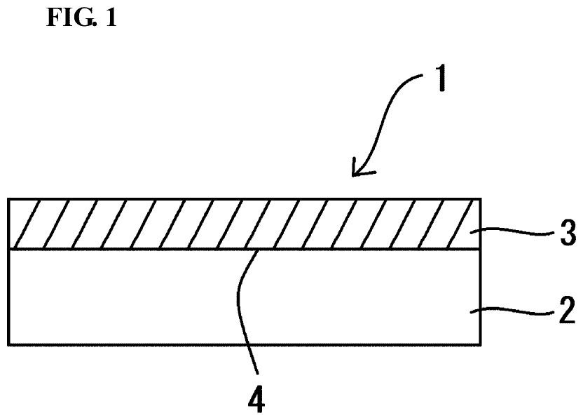

A printed circuit board substrate according to an embodiment (hereinafter, also referred to as “Embodiment 2”) of the present disclosure will be described with reference to FIG. 1. A printed circuit board substrate 1 includes a base film 2 having a first main surface 4 and a sintered body layer 3 of copper nanoparticles formed on the first main surface 4. The sintered body layer has a Cu₂O content of 3.0 mass % or less. The sintered body layer 3 has a glossiness of 300 or more.

The printed circuit board substrate 1 can have high electrical conductivity.

### <Base Film>

The base film 4 of the printed circuit board substrate 1 has an insulating property. The base film 4 is not particularly limited. A publicly known base film may be used as the base film 4. The base film 4 is, for example, a polyimide film, a polyethylene terephthalate (PET) film, a polyether ether ketone (PEEK) film, or a fluororesin film.

### <Sintered Body Layer>

The Cu₂O content in the sintered body layer 3 is 3.0 mass % or less. The upper limit of the Cu₂O content in the sintered body layer 3 may be 2.0 mass % or 1.5 mass %. The lower limit of the Cu₂O content in the sintered body layer 3 may be 0 mass %. The Cu₂O content in the sintered body layer 3 may be 0 mass % to 3.0 mass %, 0 mass % to 2.0 mass %, or 0 mass % to 1.5 mass %.

The Cu₂O concentration in the sintered body layer 3 is measured by an X-ray diffraction method using “Empyrean” (trademark) manufactured by Malvern Panalytical Ltd.

The lower limit of the glossiness of the sintered body layer 3 is 300 and may be 310 or 320. When the glossiness of the sintered body layer 3 is 300 or more, the electrical conductivity of the sintered body layer 3 improves. The upper limit of the glossiness of the sintered body layer 3 is not particularly limited but may be, for example, 500. The glossiness of the sintered body layer 3 may be 300 to 500, 310 to 500, or 320 or 500. The glossiness of the sintered body layer 3 is measured using “Gloss Checker IG-410” (trademark) manufactured by HORIBA, Ltd.

The upper limit of the resistivity of the sintered body layer 3 may be 100 μΩ·cm, 90 μΩ·cm, 80 μΩ·cm, or 60 μΩ·cm. The lower limit of the resistivity of the sintered body layer 3 is not particularly limited but may be, for example, 1.6 μΩ·cm. The resistivity of the sintered body layer 3 may be 1.6μΩ·cm to 100μΩ·cm, 1.6μΩ·cm to 90μΩ·cm, 1.6μΩ·cm to 80μΩ·cm, or 1.6μΩ·cm to 60μΩ·cm.

The resistivity of the sintered body layer 3 is measured using “Loresta-GX MCP-T700” manufactured by Nittoseiko Analytech Co., Ltd.

The sintered body layer 3 may have an average thickness of 0.01 μm to 5 μm or 0.02 μm to 3 μm. The method for measuring the average thickness of the sintered body layer 3 is as follows. The thickness is measured at five points of the sintered body layer 3 using an X-ray fluorescence spectrometer (measurement apparatus: “FT160S” (trademark) manufactured by Hitachi High-Tech Corporation). The average value of the thicknesses at the five points is the average thickness of the sintered body layer 3.

The printed circuit board substrate 1 can be used for manufacturing a printed circuit board by the subtractive process or the semi-additive process. The printed circuit board manufactured by using the printed circuit board substrate 1 has a conductive pattern including a layer formed by patterning the sintered body layer 3.

### <Method of Manufacturing Printed Circuit Board Substrate>

A method of manufacturing the printed circuit board substrate 1 includes, for example, a step of coating a base film 4 with a copper nano-ink according to Embodiment 1 (coating step), a step of drying a coating film of the copper nano-ink (drying step), and a step of firing a dry film of the copper nano-ink (firing step). In the firing step, a sintered body layer 3 is formed on the base film 4.

### <<Coating Step>>

In the coating step, a base film 2 is coated with a copper nano-ink to form a coating film.

Examples of usable methods for coating the base film with the copper nano-ink include publicly known coating methods such as a spin coating method, a spray coating method, a bar coating method, a die coating method, a slit coating method, a roll coating method, and a dip coating method. Only part of a surface of the base film 4 may be coated with the copper nano-ink using, for example, screen printing, a dispenser, or ink jetting.

### <<Drying Step>>

In the drying step, the coating film of the copper nano-ink is dried to form a dry film.

In the drying step, the coating film may be dried by heating or blowing air. The coating film may be dried by blowing hot air onto the coating film. The temperature of the hot air may be a temperature at which the solvent of the copper nano-ink does not boil. The temperature of the hot air is, for example, 15° C. to 80° C. The wind speed of the hot air may be a wind speed at which the hot air does not ripple the coating film. The wind speed of the hot air at the surface of the coating film is, for example, 5 m/s to 10 m/s.

### <<Firing Step>>

In the firing step, the dry film is fired after the drying step. Consequently, the solvent and the dispersant of the copper nano-ink in the dry film are evaporated or thermally decomposed, and the copper nanoparticles are sintered. Thus, a sintered body layer 3 is formed on one surface (first main surface 4) of the base film 4. The firing step may be performed in nitrogen gas.

When the copper nano-ink contains polyethyleneimine, in the firing step, copper oxide in the copper nano-ink is reduced to copper by a reduction reaction because polyethyleneimine has a reduction action. In addition, carbon constituting polyethyleneimine is oxidized and released as carbon dioxide.

When the copper nano-ink contains polyvinyl alcohol, copper in the dry film is less likely to oxidize because polyvinyl alcohol has oxidation resistance.

The lower limit of the firing temperature in the firing step may be 300° C. or 325° C. When the firing temperature is 300° C. or higher, copper oxide can be sufficiently reduced, and the copper nanoparticles can be completely sintered. The upper limit of the firing temperature may be 390° C. or 375° C. When the firing temperature is 390° C. or lower, copper is less likely to oxidize.

The lower limit of the firing time in the firing step may be 10 minutes or 20 minutes. When the firing time is 10 minutes or more, copper oxide can be sufficiently reduced, and the copper nanoparticles can be completely sintered. The upper limit of the firing time may be 6 hours or 4 hours. When the firing time is 6 hours or less, copper is less likely to oxidize.

In the method of manufacturing the printed circuit board substrate 1, metal may be stacked by electroless plating or electroplating on the sintered body layer of the copper nano-ink formed after the firing step. This metal layer may be thicker than the sintered body layer 4.

### EXAMPLES

The present embodiments will be more specifically described with reference to Examples. However, the present embodiments are not limited by these Examples.

### [Test 1]

In Test 1, the performances of copper nano-inks and printed circuit board substrates 1 of Embodiment 1 and copper nano-inks and printed circuit board substrates produced by existing manufacturing methods were evaluated.

### <Manufacturing of Copper Nano-Ink>

### <Sample 1 to Sample 7>

### <<Step of Precipitating Copper Nanoparticles>>

Titanium trichloride serving as a reducing agent, sodium hydroxide serving as a pH adjuster, sodium citrate serving as a complexing agent, and a dispersant were dissolved in pure water to prepare an aqueous solution of a reducing agent. The type of dispersant used in each sample is shown in the “Type of dispersant” column in Table 1. The aqueous solution of the reducing agent was prepared in a 60 L reaction tank. Next, while the aqueous solution of the reducing agent was stirred, copper nitrate trihydrate that had been held at the same temperature as the temperature of the aqueous solution of the reducing agent was put into the aqueous solution of the reducing agent to precipitate copper nanoparticles.

### <<Step of Washing Copper Nanoparticles>>

The solution containing the copper nanoparticles after the reaction was left to stand for 12 hours or more to settle the copper nanoparticles. Subsequently, about 95% of the supernatant was removed by decantation. An aqueous solution in which a dispersant was added to pure water (aqueous solution of a dispersant) was added to the solution containing the sediment of the copper nanoparticles, and stirring was performed for 60 minutes with a stirrer to prepare a liquid mixture. The type of dispersant used in each sample is shown in the “Type of dispersant” column in Table 1. The content of the dispersant in the aqueous solution of the dispersant was 30 mass %. The amount of aqueous solution of the dispersant added to the solution containing the sediment of the copper nanoparticles was 300 g.

Next, the liquid mixture after stirring was subjected to solid-liquid separation by centrifugal separation to recover a dehydrated solid containing the copper nanoparticles and the dispersant (washing with a dispersant). The rotation speed during the centrifugal separation was 15,000 rpm.

Five liters of pure water was added to the solid, the solid was dispersed with a mixer, and centrifugal separation was then performed to recover the dehydrated solid (washing with pure water). The washing with pure water was performed again to recover the solid containing copper nanoparticles.

### <<Step of Dispersing Copper Nanoparticles>>

Next, pure water was added to the solid containing copper nanoparticles to disperse the solid, thus obtaining a copper nano-ink.

### <Sample 1-1 to Sample 1-5>

Copper nanoparticles were precipitated in the same manner as in Sample 1 to Sample 7.

### <<Step of Separating Copper Nanoparticles>>

Next, the aqueous solution of the reducing agent, the aqueous solution containing the precipitated copper nanoparticles, was subjected to centrifugal separation, so that the aqueous solution was separated into a copper nanoparticle concentrated liquid containing copper nanoparticles and a liquid phase with a centrifugal separator.

### <<Step of Dispersing Copper Nanoparticles>>

In Sample 1-2 to Sample 1-4, the copper nanoparticle concentrated liquid containing copper nanoparticles was filtered, and pure water was then added thereto to obtain a copper nano-ink.

In Sample 1-1 and Sample 1-5, polyethyleneimine (PEI) and citric acid were added to the dispersion liquid of copper nanoparticles. Subsequently, the content of each component was adjusted with pure water to obtain a copper nano-ink having the composition shown in the “Copper nano-ink composition” column in Table 1.

In Sample 1-6, polyethyleneimine, polyvinyl alcohol, and citric acid were added to the dispersion liquid of copper nanoparticles. The content of each component was adjusted with pure water to obtain a copper nano-ink having the composition shown in the “Copper nano-ink composition” column in Table 1. Sample 1-6 corresponds to Sample 18 in Examples of PTL 1.

TABLE 1
Table 1

| | | | Copper nano-ink composition | | | | |
|---|---|---|---|---|---|---|---|
| | | Washing | Copper | | | Polyvinyl | |
| Sample | | with | nanoparticle | Polyethyleneimine | Polyvinylpyrrolidone | alcohol | Citric acid |
| No. | Type of dispersant | dispersant | mass% | mass % | mass % | mass % | mass % |
| 1 | Polyethyleneimine | Performed | 25 | 0.4 | — | — | — |
| 2 | Polyvinylpyrrolidone | Performed | 25 | — | 0.4 | — | — |
| 3 | Polyvinyl alcohol | Performed | 25 | — | — | 0.4 | — |
| 4 | Polyethyleneimine | Performed | 5 | 2.5 | — | — | — |
| 5 | Polyethyleneimine | Performed | 60 | 0.02 | — | — | — |
| 6 | Polyvinyl alcohol | Performed | 25 | — | — | 0.1 | — |
| 7 | Polyvinyl alcohol | Performed | 50 | — | — | 0.1 | — |
| 1-1 | Polyethyleneimine | Not | 25 | 0.4 | — | — | 2.0 |
| | | performed | | | | | |
| 1-2 | Polyethyleneimine | Not | 25 | 0.4 | — | — | — |
| | | performed | | | | | |
| 1-3 | Polyvinylpyrrolidone | Not | 25 | — | 0.4 | — | — |
| | | performed | | | | | |
| 1-4 | Polyvinyl alcohol | Not | 25 | — | — | 0.4 | — |
| | | performed | | | | | |
| 1-5 | Polyethyleneimine | Not | 5 | 2.5 | — | — | 2.0 |
| | | performed | | | | | |
| 1-6 | Polyethyleneimine | Not | 25 | 2.0 | — | 0.4 | 3.2 |
| | | performed | | | | | |

### <Measurement of Copper Nano-Ink>

For each of the copper nano-inks immediately after the manufacturing, the first mean particle size of the copper nanoparticles, the second mean particle size of the copper nanoparticles, the first ratio, and the second ratio were measured. The methods for measuring these items are as described in Embodiment 1. The results are shown in Table 2. Of copper oxide and copper hydroxide, the component with the highest mass ratio in each sample is shown in “Component with highest mass ratio” in Table 2. In all the samples, the copper nanoparticles contained at least one of copper oxide and copper hydroxide.

TABLE 2
Table 2

| | Copper nano-ink | | | | | Sintered body layer | | |
|---|---|---|---|---|---|---|---|---|
| | First mean | Second mean | (M2 / M1) × | | (C2 / C1) × | | Cu₃O | |
| Sample | particle size | particle size | 100 | Component with | 100 | | content | Resistivity |
| No. | nm | nm | % | highest mass ratio | % | Glossiness | mass% | μΩ•cm |
| 1 | 70 | 80 | 2.0 | Cu₂O | 0.15 | 360 | 4.50 | 50 |
| 2 | 20 | 25 | 4.0 | CuO | 0.30 | 380 | 2.50 | 8 |
| 3 | 150 | 175 | 2.4 | Cu(OH)₂ | 0.06 | 320 | 0.60 | 80 |
| 4 | 1 | 5 | 5.0 | Cu₂O | 0.45 | 400 | 3.00 | 5 |
| 5 | 200 | 250 | 0.1 | Cu₂O | 0.02 | 320 | 0.15 | 60 |
| 6 | 200 | 400 | 3.0 | Cu(OH)₂ | 0.02 | 310 | 2.00 | 50 |
| 7 | 200 | 600 | 4.0 | Cu(OH)₂ | 0.04 | 300 | 3.00 | 80 |
| 1-1 | 70 | 80 | 6.0 | Cu₂O | 0.60 | 280 | 4.00 | 120 |
| 1-2 | 70 | 100 | 6.0 | Cu₂O | 0.60 | 250 | 5.00 | 200 |
| 1-3 | 20 | 40 | 8.0 | CuO | 1.00 | 300 | 6.00 | 120 |
| 1-4 | 150 | 500 | 6.5 | Cu(OH)₂ | 0.35 | 250 | 6.00 | 160 |
| 1-5 | 1 | 5 | 12.0 | Cu₂O | 1.50 | 290 | 10.00 | 110 |
| 1-6 | 80 | 420 | 5.6 | Cu₂O | 0.50 | 290 | 0.00 | 120 |

### <Production of Printed Circuit Board Substrate>

### <<Coating Step and Drying Step>>

A polyimide film having an average thickness of 25 μm was used as a base film. One surface of the polyimide film was coated with the copper nano-ink of each sample by a bar coating method. The resulting coating film was dried at room temperature by blowing air to form a dry film.

### <<Firing Step>>

Next, the dry film was fired in a hot-air oven filled with nitrogen gas at a firing temperature of 350° C. for a firing time of 30 minutes to form a sintered body layer having an average thickness of 0.2 μm. Thus, a printed circuit board substrate of each sample was obtained.

### <Measurement of Printed Circuit Board Substrate>

For each of the printed circuit board substrates immediately after the manufacturing, the glossiness of the sintered body layer, the Cu₂O content in the sintered body layer, and the resistivity of the sintered body layer were measured. The methods for measuring these items are as described in Embodiment 1. The results are shown in Table 2. In the case where the resistivity of the sintered body layer is 100 μΩ·cm or less, the resistivity of the sintered body layer is determined to be low, and a printed circuit board substrate including this sintered body layer is determined to have high electrical conductivity.

### Discussion

The copper nano-inks and the printed circuit board substrates of Sample 1 to Sample 7 correspond to Examples. The copper nano-inks and the printed circuit board substrates of Sample 1-1 to Sample 1-6 correspond to Comparative Examples. The sintered body layers of the printed circuit board substrates of Sample 1 to Sample 7 (Examples) have lower resistivities than the sintered body layers of the printed circuit board substrates of Sample 1-1 to Sample 1-6 (Comparative Examples). Thus, the printed circuit board substrates of Sample 1 to Sample 7 (Examples) have higher electrical conductivities than the printed circuit board substrates of Sample 1-1 to Sample 1-6 (Comparative Examples).

The first mean particle sizes of the copper nanoparticles of Sample 1 and Sample 1-2 are each 70 nm. The second mean particle size of the copper nanoparticles of Sample 1 is 80 nm, and the second mean particle size of the copper nanoparticles of Sample 1-2 is 100 nm. Accordingly, in Sample 1, the copper nanoparticles are less likely to aggregate, and the dispersibility of the copper nanoparticles is improved compared with Sample 1-2. Moreover, the first ratio and the second ratio in Sample 1 are smaller than those in Sample 1-2.

The first mean particle sizes of the copper nanoparticles of Sample 2 and Sample 1-3 are each 20 nm. The second mean particle size of the copper nanoparticles of Sample 2 is 25 nm, and the second mean particle size of the copper nanoparticles of Sample 1-3 is 40 nm. Accordingly, in Sample 2, the copper nanoparticles are less likely to aggregate, and the dispersibility of the copper nanoparticles is improved compared with Sample 1-3. Moreover, the first ratio and the second ratio in Sample 2 are smaller than those in Sample 1-3.

The first mean particle sizes of the copper nanoparticles of Sample 3 and Sample 1-4 are each 150 nm. The second mean particle size of the copper nanoparticles of Sample 3 is 175 nm, and the second mean particle size of the copper nanoparticles of Sample 1-4 is 500 nm. Accordingly, in Sample 3, the copper nanoparticles are less likely to aggregate, and the dispersibility of the copper nanoparticles is improved compared with Sample 1-4. Moreover, the first ratio and the second ratio in Sample 3 are smaller than those in Sample 1-4.

Sample 1 and Sample 1-2 were compared, Sample 2 and Sample 1-3 were compared, and Sample 3 and Sample 1-4 were compared. From these comparison results, it is presumed that the step of washing the copper nanoparticles contributes to the tendency of the copper nanoparticles not to aggregate, the improvement in the dispersibility of the copper nanoparticles, the reduction in the first ratio, and the reduction in the second ratio.

### [Test 2]

In Test 2, the copper nano-ink of Sample 1 was sealed and stored for three months, and the first mean particle size, the second mean particle size, the first ratio, and the second ratio of this copper nano-ink were then measured. A printed circuit board substrate was produced using this copper nano-ink in the same manner as in Sample 1, and the glossiness and the resistivity of the sintered body layer were measured. The results are shown in Table 3. In Table 3, the copper nano-ink of “Sample 2-1” is the copper nano-ink obtained after the copper nano-ink of Sample 1 was sealed and stored for three months. The sintered body layer of “Sample 2-1” is a sintered body layer formed using the copper nano-ink obtained after the copper nano-ink of Sample 1 was sealed and stored for three months.

TABLE 3
Table 3

| | Copper nano-ink | | | | Sintered body layer | |
|---|---|---|---|---|---|---|
| | First mean | Second mean | (M2 / M1) × | (C2 / C1) × | | |
| Sample | particle size | particle size | 100 | 100 | | Resistivity |
| No. | nm | nm | % | % | Glossiness | μΩ•cm |
| 2-1 | 70 | 100 | 2.8 | 0.15 | 330 | 60 |

### Discussion

In the copper nano-ink (copper nano-ink of Sample 2-1) obtained after the copper nano-ink of Sample 1 was sealed and stored for three months, aggregation and oxidation slightly proceeded. However, the sintered body layer of the printed circuit board substrate produced using the copper nano-ink after three-month storage has a low resistivity, and the printed circuit board substrate has high electrical conductivity.

Although the embodiments and Examples of the present disclosure have been described above, appropriate combinations and various modifications of configurations of the embodiments and Examples described above are originally intended.

It is to be understood that the embodiments and Examples disclosed herein are only illustrative and non-restrictive in all respects. The scope of the present invention is defined not by the embodiments and Examples described above but by the appended claims and is intended to include all modifications that fall within the scope of the claims and the equivalents thereof.

### REFERENCE SIGNS LIST

1 printed circuit board substrate
2 base film
3 sintered body layer
4 first main surface

1. A copper nano-ink comprising copper nanoparticles and a solvent,
wherein the copper nanoparticles have a first mean particle size of 1 nm to 200 nm,
the first mean particle size is a volume-based mean diameter obtained by analyzing a scanning electron microscope image of the copper nanoparticles,
the copper nanoparticles contain at least one of copper oxide and copper hydroxide, and
in the copper nano-ink, a first ratio is 5.0% or less, the first ratio being a ratio of a mass ratio M2 of a total of copper oxide and copper hydroxide to a mass ratio M1 of copper, the mass ratio M2 and the mass ratio M1 being measured by a reference intensity ratio method.

2. The copper nano-ink according to claim 1, wherein, in the copper nano-ink, a second ratio is 0.3% or less, the second ratio being a ratio of a mass-based chlorine content C2 measured by ion chromatography to a mass-based copper content C1 measured by ICP emission spectroscopy.

3. The copper nano-ink according to claim 1, wherein the copper nanoparticles have a second mean particle size of 5 nm to 400 nm, and
the second mean particle size is a number-based mean diameter measured using an ultrasonic attenuation particle size distribution analyzer.

4. The copper nano-ink according to claim 1, wherein the first ratio is 0.1% or more.

5. A printed circuit board substrate comprising:
a base film having a first main surface; and
a sintered body layer of copper nanoparticles formed on the first main surface,
wherein the sintered body layer has a Cu₂O content of 3.0 mass % or less, and
the sintered body layer has a glossiness of 300 or more.

6. The printed circuit board substrate according to claim 5, wherein the sintered body layer has a resistivity of 100μΩ·cm or less.

7. A method of manufacturing the printed circuit board substrate according to claim 5, the method comprising:
coating the base film with the copper nano-ink according to claim 1;
drying a coating film of the copper nano-ink; and
firing a dry film of the copper nano-ink,
wherein, in the firing, the sintered body layer is formed on the base film.
